(19) United States
(12) Patent Application Publication
(10) Pub. No.: US 2026/0367735 A1
(43) Pub. Date: Nov. 19, 2026

(54) WIRELESS CHARGER DETECTION FOR TOUCHSCREEN DEVICES

(71) Applicant: STMicroelectronics International N.V., Geneva (CH)

(72) Inventors: Bin Fan, Beijing (CN); Da Man, Beijing (CN); Pengcheng Wen, Beijing (CN)

(21) Appl. No.: 19/206,253

(22) Filed: May 13, 2025

(51) Int. Cl. G06F 3/041; G01R 29/26; G06F 3/044

(52) U.S. Cl. CPC G06F 3/04182; G01R 29/26; G06F 3/04166; G06F 3/0446

(57) ABSTRACT

A method for detecting and mitigating noise interference from wireless chargers includes setting a sensing frequency for an external noise scan on a touchscreen device to a ping signal frequency range corresponding to a wireless charger, performing the external noise scan at the sensing frequency, collecting external noise data from the external noise scan, calculating a current standard deviation from the collected external noise data, determining whether the current standard deviation exceeds a first threshold, in response to the current standard deviation exceeding the first threshold, entering an external noise mode, and applying a filtering technique in response to being in the external noise mode.

### TECHNICAL FIELD

The present application relates generally to touchscreen devices and, in particular embodiments, to a system and method for detecting and mitigating noise interference from wireless chargers.

### BACKGROUND

Touchscreen technology has become ubiquitous in modern mobile devices, particularly in smartphones. Wireless charging has become a standard feature in many smartphones, allowing users to charge their devices by simply placing them on a compatible wireless charging pad or wireless charger. These mobile devices typically include charging coils designed to overlap with coils on the wireless charger. When a wireless charger and a mobile device are properly aligned, the charging coils overlap completely to enable efficient power transfer. In this configuration, the device typically enters a wireless charging mode.

As smartphone technology has evolved, foldable smartphones have emerged as a popular form factor, offering users the flexibility of both phone and tablet-like experiences in a single device. However, users sometimes place unfolded phones on wireless chargers, using them as holders or stands rather than for charging purposes. In these scenarios, the coils may not properly overlap to meet the wireless charging conditions which may cause the charger to continuously send ping signals in attempts to establish a connection with the device.

Wireless charging systems operate using specific frequencies to establish connections between charging devices and mobile phones. These ping signals from wireless chargers can interfere with touch controller operation. The interference manifests as noise in the touch sensing data, potentially leading to false touch detections on the screen. The interference patterns can be variable and unpredictable, making them difficult to identify and filter using conventional signal processing techniques. This interference can significantly impact user experience by generating ghost touch points on the screen when no actual finger contact is present.

### SUMMARY

Embodiments of the present application provide a method for detecting and mitigating external noise interference on touchscreen devices. As discussed below, embodiments relate to touchscreen devices operating in proximity to wireless chargers.

One general aspect includes a method that includes setting a sensing frequency for an external noise scan on a touchscreen device to a ping signal frequency corresponding to a wireless charger, performing the external noise scan at the sensing frequency, collecting external noise data from the external noise scan, calculating a current standard deviation from the collected external noise data, determining whether the current standard deviation exceeds a first threshold, in response to the current standard deviation exceeding the first threshold, entering an external noise mode, and applying a filtering technique in response to being in the external noise mode.

Another general aspect includes a method that includes performing external noise scans at a plurality of sensing frequencies corresponding to ping signal frequencies of wireless chargers, collecting external noise data from the external noise scans for each of the plurality of sensing frequencies, calculating a current standard deviation for each of the plurality of sensing frequencies from the collected external noise data, determining whether the current standard deviation for each of the sensing frequencies exceeds a threshold, and in response to the current standard deviation exceeding the threshold, entering an external noise mode.

Another general aspect includes a device that includes a touchscreen, a touchscreen controller, and a non-transitory memory storing a program to be executed by the touch controller. The program includes instructions to perform an external noise scan at a ping signal frequency of an electronic device for a plurality of frames, collect external noise data from the external noise scan for each frame of the plurality of frames, store the collected external noise data for each frame in a FIFO buffer, determine a standard deviation for a current frame from the stored external noise data in the FIFO buffer, determine whether the standard deviation for the current frame is greater than a threshold, and operate in an external noise mode in response to the standard deviation in the current frame exceeding the threshold.

Other embodiments and variations are described herein.

### BRIEF DESCRIPTION OF THE DRAWINGS

For a more complete understanding of the present application, and the advantages thereof, reference is now made to the following descriptions taken in conjunction with the accompanying drawings, in which:

FIGS. 1A-1B illustrate a component schematic of an electronic device according to an embodiment of the present application;

FIGS. 2A-2D illustrate schematic representations of a touchscreen device and wireless charging system according to embodiments of the present application;

FIGS. 3A-3F illustrate external noise data and touch bitmaps of a touchscreen device according to an embodiment of the present application;

FIG. 4 illustrates a scanning process according to an embodiment of the present application;

FIG. 5 illustrates storing noise data for special scans according to an embodiment of the present application;

FIGS. 6A and 6B illustrate flowcharts for an external noise mode process according to embodiments of the present application;

FIGS. 7 and 8 illustrate scanning processes according to an embodiment of the present application;

FIG. 9 illustrates storing external noise data of a special scan according to an embodiment of the present application;

FIG. 10 illustrates a graph showing a relationship between sensing frequencies and standard deviations according to embodiments of the present application; and

FIG. 11 illustrates a flowchart of a method for detecting and filtering wireless charger noise according to embodiments of the present application.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Touchscreen devices can experience noise interference when placed on or near external electronic devices that emit electromagnetic signals. Noise interference may come from various internal and external sources including, for example, wireless chargers, power supplies, display drivers, radio frequency (RF) transmitters, and other electronic components operating in proximity to the touch screen. The noise interference may cause touch input processing issues, such as mistouches and ghost touches.

Known approaches for handling noise interference in touchscreen devices may not adequately address varied noise patterns generated by external noise interference. For example, touch controllers may experience interference when a touchscreen device is placed near a wireless charger that continues to emit ping signals. Additionally, existing approaches often implement fixed filtering parameters that cannot adapt to different noise characteristics. A one-size-fits-all approach may unnecessarily impact touch sensitivity during normal operation. The lack of adaptation based on actual noise characteristics can result in either insufficient filtering of noise-induced ghost touches or excessive filtering that degrades legitimate touch detection.

Embodiments of the present disclosure relate to a method and system detecting and filtering external noise interference on touchscreen devices. In various embodiments, a touchscreen device employs a special scan to detect and filter external wireless charger noise that can cause ghost touch points. For example, when a touchscreen device is placed on a wireless charger, the wireless charger sends a ping signal to connect to the touchscreen device for charging. However, wireless charger continues to send ping signals to the device when coils on the wireless charger are not properly aligned with the touchscreen device.

The ping signals from the wireless charger can interfere with touch detection on the touchscreen device, such as unwanted ghost touch on the screen. The present application addresses this issue by implementing a special scan that can be tuned to specific sensing frequencies associated with wireless charger ping signals. The method can be beneficial for foldable touchscreen devices placed on wireless chargers in an unfolded configuration, for example, when a user is using the wireless charger as a stand or prop to view the unfolded screen of the touchscreen device.

In various embodiments, the special scan can be configured to perform at multiple sensing frequencies to identify various types of wireless chargers that may be causing noise interference. By detecting and adapting to the external noise data, the touchscreen device can maintain stable touch performance for noise interference caused by wireless chargers that operate at different frequencies.

In various embodiments, a touch controller implements a scan sequence designed to detect external wireless charger noise at frequencies commonly used by wireless charging devices. When noise interference from a wireless charger is detected, the touch controller can apply filtering parameters to prevent ghost touches that can interfere with touchscreen operations. The filtering technique may include implementing touch delay filtering, where touch events are only registered after persisting for a specified number of frames, as well as applying shape-based filtering to identify and reject touch patterns characteristic that indicate noise interference from wireless chargers.

The special scan can be implemented within existing touch controller firmware without requiring hardware modifications, making it suitable for deployment through software updates to devices already in use. By identifying and filtering wireless charger interference, a stable touch experience can be provided when external noise interference from wireless chargers is present, particularly when foldable devices are used in an unfolded configuration on or near wireless chargers.

Embodiments of the present application provide adaptive noise detection and filtering techniques for wireless charger interference. Embodiments of the present application can apply appropriate filtering techniques when needed based on detected noise levels. Various embodiments of the present disclosure provide techniques for dynamically adjusting touch filtering parameters based on statistical analysis of collected external noise data.

While the inventive aspects are described primarily in the context of foldable smartphones experiencing interference from wireless chargers, it should also be appreciated that these inventive aspects may also apply to various touch-enabled devices operating in environments with electromagnetic interference. In particular, aspects of this disclosure may similarly apply to tablets, laptops with touch screens, smart displays, automotive touch panels, industrial control panels, point-of-sale terminals, and other touch-enabled devices that might experience interference from external electromagnetic sources such as wireless chargers, radio frequency identification (RFID) readers, near-field communication (NFC) devices, or other equipment that generates electromagnetic fields at various frequencies.

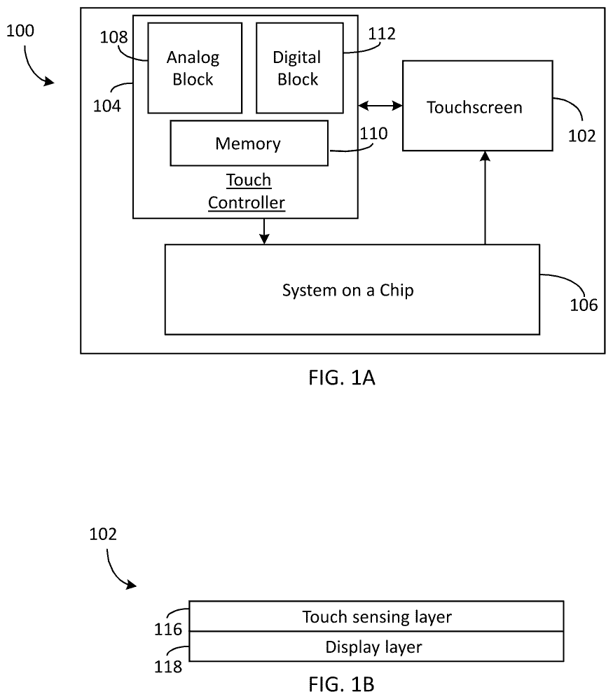

FIGS. 1A-1B illustrate a component schematic of a touchscreen device according to an embodiment of the present application.

FIG. 1A illustrates a component schematic of a touchscreen device 100 that includes a touchscreen 102, a touch controller 104, and a system on a chip 106. The touchscreen device 100 may be a smartphone, a GPS device, a tablet computer, a mobile media player, a laptop, a gaming system, a personal computer, wearable device, or any other electronic device that may utilize touch sensitive display.

The touchscreen 102 may be an organic light emitting diode (OLED) display, an LED display, or any other type of display. The touchscreen 102 may include a plurality of pixels in a display layer configured to display an image. As understood by those with ordinary skill in the art, the display layer of the touchscreen 102 may include of the plurality of pixels positioned at each of the intersections between the data lines and scan lines. The plurality of scan lines may extend across the rows of the touchscreen 102, and data lines that extend across the columns of the touchscreen 102 in a matrix like formation. The touchscreen 102 may also include a touch sensing layer configured to detect touch inputs made on the touchscreen 102. This will be shown in more detail below.

The touch controller 104 may perform various methods with respect to the display. In various embodiments, the touch controller 104 may be a processor that analyzes information and carries out a series of executable scripts, e.g., stored in a memory 110. In one or more embodiments, the processor may comprise an application-specific integrated circuit (ASIC) device, a central processing unit (CPU), or any other processing unit known in the art. In various embodiments, the touch controller 104 may comprise a number of separate computing units such as cores integrated within one processor, or distinct separate processing chips. Further details regarding how the touch controller 104 accounts for water on the touchscreen 102 are provided below.

In various embodiments, the touch controller 104 may include an analog block 108 and a digital block 112. The analog block 108 may include a plurality of analog circuits configured to measure capacitances across touchscreen 102 and convert them into digital values. The digital block 112 may comprise a variety of digital logic circuits such as DACs or digital control systems configured to obtain digital touch data from the analog block 108, process the digital touch data and store them into memory 110.

The memory 110 may be configured to store data and instructions for the touch controller 104 and comprise various programs to be executed by the touch controller 104. The memory 110 may include a non-transitory computer readable medium that stores instructions for execution by the touch controller 104. The memory 110 may comprise both volatile and non-volatile components to support temporary data storage during processing and long-term storage of system software and calibration data. The volatile memory, typically RAM, provides fast access for temporary storage of sensor data, intermediate results, and current state information for a gesture recognition system. The non-volatile memory, such as Flash or EEPROM, can store information such as the device's firmware, gesture recognition algorithms, and sensor calibration data.

In various embodiments, the system on a chip 106, may also be known as an application processor, and may comprise a processor, interface, circuitry, and/or the like configured to direct the flow of input and output data to the touchscreen 102 and the associated touch controller 104. The system on a chip 106 may be configured to receive touch event data from the touch controller 104 and interpret the touch event data based on a user interface or application displayed on the touchscreen 102.

Additionally, the touch controller 104 may be configured to detect touch inputs via a touchscreen 102. In other words, the touch controller 104 may be configured to send touch driving signals (TDS) to the touchscreen, receive touch sensing signals (TSS) in return from the touchscreen, process the TSS to determine coordinates of touch, and report them to the system on a chip 106. Then based on the strength data collected from scanning, the touchscreen may be used by the touch controller 104 to determine the coordinates of touch, and report them to the system on a chip 106. Then, the system on a chip 106 may provide an output to the touchscreen 102 based on the reported coordinates of touch.

In various embodiments, the touch controller 104 is configured to execute a process for detecting and mitigating noise interference from wireless chargers in touchscreen devices. The touch controller 104 can perform a special scan for collecting external noise data at sensing frequencies tuned to match common wireless charger ping signal frequencies. In one or more embodiments, a wireless charger can be tested to determine the ping signal frequency and the determined ping signal frequency can be stored as a sensing frequency to tune the special scan in the touch controller 104 to detect noise interference from the wireless charger.

Advantageously, as will be described in more detail below, embodiments of the present application disclose a touchscreen device configured to detecting noise interference from wireless chargers in touchscreen devices, and a method for mitigating the noise interference from wireless chargers.

FIG. 1B illustrates a schematic of the touchscreen 102. In various embodiments, the touchscreen 102 may include a touch sensing layer 116 and a display layer 118. The touch sensing layer 116 and the display layer 118 may be situated on the front-facing side of the touchscreen device 100. The touch sensing layer 116 is configured to detect touch inputs made on the touchscreen 102.

The touch sensing layer 116 includes a plurality of TX channels (e.g., drive channels) and RX channels (e.g., sense channels) arranged in rows and columns across the touchscreen 102. The TX channels and the RX channels form the touch sensing layer. The TX channels and RX channels may span the entirety of the touchscreen 102 in a grid-like fashion that are operable by a touch controller. In various embodiments, the TX channels may be formed in rows across the touchscreen and the RX channels 124 may be formed in columns across the touchscreen 102. In other embodiments, the RX channels 124 may be formed in rows across the touchscreen 102 and the TX channels 122 may be formed in columns across the touchscreen 102. The TX channels 122 and the RX channels 124 may overlap in certain embodiments.

The TX channels and the RX channels may be formed by electrically coupling the touchscreen 102 to rows of electrodes (e.g., TX electrodes or RX electrodes) and columns of electrodes (e.g., TX electrodes or RX electrodes) that span the entirety of the touchscreen 102. In various embodiments, the TX channels and the RX channels have a measurable mutual capacitance at their intersections. In some embodiments, the TX channels and the RX channels may have a self-capacitance that can be measured with respect to ground.

The touch controller 104 is coupled to the TX channels and the RX channels that form the touch sensing layer 116. The TX channels 122 and the RX channels 124 create a matrix of intersections that act as individual touch sensors. The touch controller 104 sends electrical signals through the TX channels and measures the changes in capacitance at each intersection point through the RX channels. The touch controller detects and locates touch events by analyzing the changes in capacitance across the touchscreen 102. The touch events may include a finger touch, stylus or pen touch, or any contact with that touchscreen 102 that changes the capacitance in the touch sensing layer 116. For convenience, these are all referred to as a touch input herein. The touch controller 104 can processes this raw data, determine the noise levels, apply noise filters corresponding to the noise levels, and interpret the touch inputs, translating them into coordinates and gestures that the device's operating system can understand. This integration between the touch controller and the touch sensing layer enables accurate and responsive touch detection.

In one or more embodiments, the touch controller 104 enables only the Rx channels to collect external noise data without driving the TX channels during a special scan used to detect noise interference from wireless chargers. The special scan can collect a plurality of frames or samples of the external noise data caused by a wireless charger. The collected external noise data can be stored in memory 110 of the touch controller 104. For example, the collected external noise data may be stored in a first-in-first-out (FIFO) buffer is updated for every frame. Standard deviation calculations can be performed using the stored external noise data to determine the degree of noise dispersion, with larger standard deviation values indicating greater noise interference.

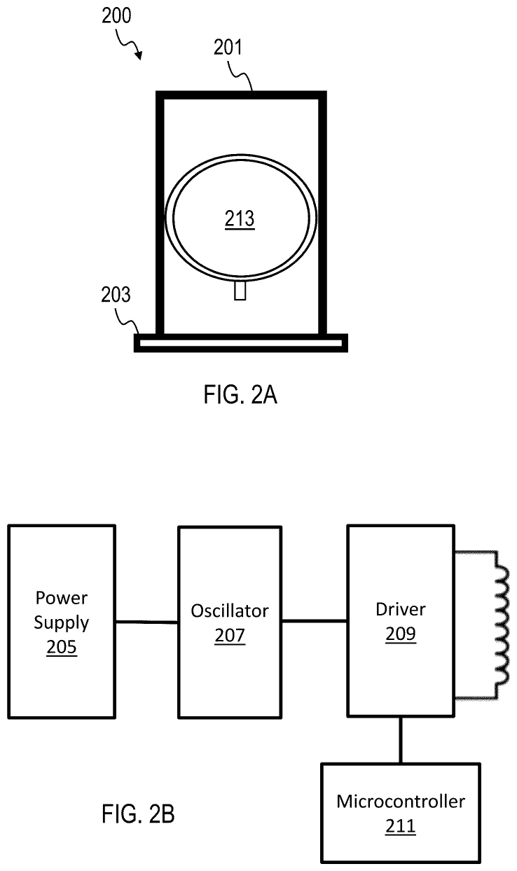

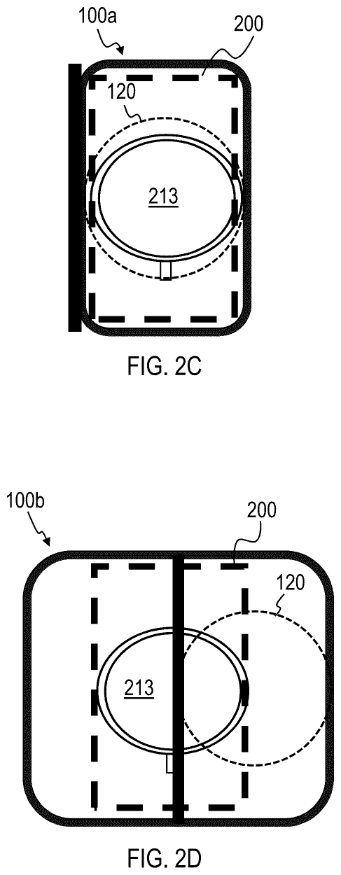

FIGS. 2A-2D illustrate schematic representations of a touchscreen device and wireless charging system according to embodiments of the present application. FIGS. 2A-2D will be described in conjunction with FIGS. 1A and 1B.

FIG. 2A illustrates a schematic representation of a wireless charger 200 according to embodiments of the present application. The wireless charger 200 shows a housing 201 for components of the wireless charger including a transmitter coil 213, and base 203 that provides support a touchscreen device.

In one or more embodiments, the base 203 of the wireless charger 200 can function as a stand or holder for touchscreen device 100 during wireless charging. In some cases, the wireless charger 200 may be used only as a stand. For example, a user may place the unfolded touchscreen device on the wireless charger 200 to use the full open touchscreen without intending to charge the touchscreen device 100. In some embodiments, the wireless charger 200 may be a wireless charging pad that can be placed flat on a surface or positioned within a surface, for example, on or in a table top or desktop.

While the inventive aspects are described primarily in the context of a wireless charging stand, it should also be appreciated that these inventive aspects may also apply to other configurations for wireless chargers, such as, magnetic wireless chargers, flat or propped wireless charging pads, wireless charging mats, portable or battery operated wireless chargers, or built-in wireless chargers, for example, wireless chargers built into a vehicle console or table top. In particular, aspects of this disclosure may apply to any wireless charger that provides wireless charging capabilities to touchscreen devices.

In various embodiments, the housing 201 provide structural support and protection for the components of the wireless charger 200. In various embodiments, the components of the wireless charger 200 may include a power supply circuit 205, an oscillator circuit 207, a driver circuit 209, a microcontroller 211, and a transmitter coil 213 as shown in FIG. 2B. The power supply circuit can convert AC power from a wall outlet to the appropriate DC voltage required by the internal circuitry. The oscillator circuit 207 can generate high-frequency alternating current at specific frequencies. The driver circuit 209 can be implemented to amplify the signal from the oscillator circuit 207 to provide sufficient power to the transmitter coil 213 through configurations such as half-bridge or full-bridge inverters. The microcontroller 211 can manage the charging process including generating ping signal and power transfer. The transmitter coil 213 can provide a wireless charging connection for a touchscreen device 100. The internal components enable the wireless charger 200 to detect compatible devices, negotiate power transfer parameters, deliver appropriate power, and maintain safe operating conditions throughout the charging process.

In various embodiments, the transmitter coil 213 can be a coiled copper conductor configured to generate an electromagnetic field when energized with alternating current. The transmitter coil 213 creates an electromagnetic field that induces current to provide wireless power transfer to a touchscreen device 100. The transmitter coil 213 may be positioned in an upper surface of the wireless charger to maximize the contact area with a receiver coil of a touchscreen device 100, for example, in a center portion of the housing 201.

In various embodiments, the transmitter coil 213 continuously monitors for changes in its electromagnetic field that would indicate the presence of a receiver coil of a touchscreen device 100. When a touchscreen device 100 is placed on the wireless charger 200, the transmitter coil 213 detects a change in the load characteristics of its electromagnetic field due to the coupling with the receiver coil. Upon detecting a touchscreen device, the transmitter coil 213 initiates communication with the touchscreen device 100 to deliver power to the receiver coil of the touchscreen device 100.

In various embodiments, the transmitter coil 213 emits low-power ping signals at specific frequencies when a receiver coil of a touchscreen device is detected in proximity to the wireless charger 200. In various embodiments, the ping signals can operate in standardized frequency ranges such as 111 kHz, 135-145 kHz, or 170-180 kHz based on wireless charging protocols. When a touchscreen device is properly aligned on the wireless charger, the transmitter coil 213 establishes a connection to charge the touchscreen device 100. However, when the touchscreen device 100 is improperly aligned, the transmitter coil 213 can continuously emit ping signals through the transmitter coil 213 in attempt to establish a proper connection.

The continuous ping signals from the transmitter coil 213 can create electromagnetic fields that can interfere with nearby electronic components, and in particular, the capacitive sensing elements of a touchscreen device 100. The electromagnetic interference generated by the transmitter coil 213 during the continuous ping process can induce currents in the touch sensing layer 116 that can lead to false touch detections or ghost touches on the display.

FIG. 2C illustrates a schematic representation of a touchscreen device 100 in a folded state 100a positioned on a wireless charger 200. In one or more embodiments, the touchscreen device 100 may be a foldable touchscreen device. The touchscreen device 100 includes a receiver coil 120 positioned in the back or rear side of the touchscreen device 100. The receiver coil 120 is configured to detect a transmitter coil 213 from a wireless charger 200. In the folded state, the receiver coil 120 of the touchscreen device 100 can be properly aligned with the transmitter coil 213 of the wireless charger 200.

When the transmitter coil 213 and the receiver coil 120 are properly aligned, the wireless charger 200 can successfully establish a connection with the touchscreen device 100 to perform wireless charging on the touchscreen device 100. When the coils are aligned as shown in FIG. 2C, the wireless charger 200 does not continue to emit ping signals once the power transfer contract has been established. FIG. 2C represents the standard use case for wireless charging of a touchscreen device 100 in its folded state 100a on a wireless charger 200.

FIG. 2D illustrates a schematic representation a touchscreen device 100 in an unfolded state 100b positioned on the wireless charger 200. As shown in FIG. 2C, touchscreen device 100 includes a receiver coil 120 positioned in the back or rear side of the touchscreen device 100. While the receiver coil 120 is still positioned in the back or rear side of the touchscreen device 100, the receiver coil 120 may be positioned on the right panel or left panel of the touchscreen device 100 in the unfolded or open state 100b. Although not shown, the touchscreen device 100 can be placed on the wireless charger 200 with the receiver coil 120 being on the right, left, top, or bottom of the touchscreen device 100 in the unfolded state based on the orientation of the touchscreen device 100 on the wireless charger 200.

In the unfolded state 100b, the receiver coil 120 of the touchscreen device 100 is not properly aligned with the transmitter coil 213 of the wireless charger 200. In various embodiments, the receiver coil 120 and transmitter coil 213 may not be properly aligned to satisfy wireless charging conditions when the coils partially overlap or do not overlap. The wireless charging conditions may be satisfied when the transmitter coil 213 and the receiver coil 120 overlap by a specific percentage, for example, 70% to 100%.

When the transmitter coil 213 and the receiver coil 120 are not properly aligned, the wireless charger will not be able to establish a proper connection for wireless charging. The wireless charger 200 continues to emit ping signals in attempt to establish a connection with the touchscreen device 100. The ping signals can generate electromagnetic interference that can affect the touchscreen controller of the touchscreen device 100. The ping signals can cause touch detection interference on the touchscreen devices 100, particularly when the transmitter coil 213 and receiver coil 120 are not aligned according to wireless charging conditions but remain in proximity to one another. The electromagnetic interference from these ping signals can cause unwanted ghost touch to appear on the screen when no actual touch input is present.

While the inventive aspects are described primarily in the context of a foldable smartphone, it should also be appreciated that these inventive aspects may also apply to non-foldable touchscreen devices, such as smartphones, tablets, smartwatches, fitness trackers, and the like. In particular, aspects of this disclosure may apply to any electronic device that utilizes a touchscreen interface capable of wireless charging.

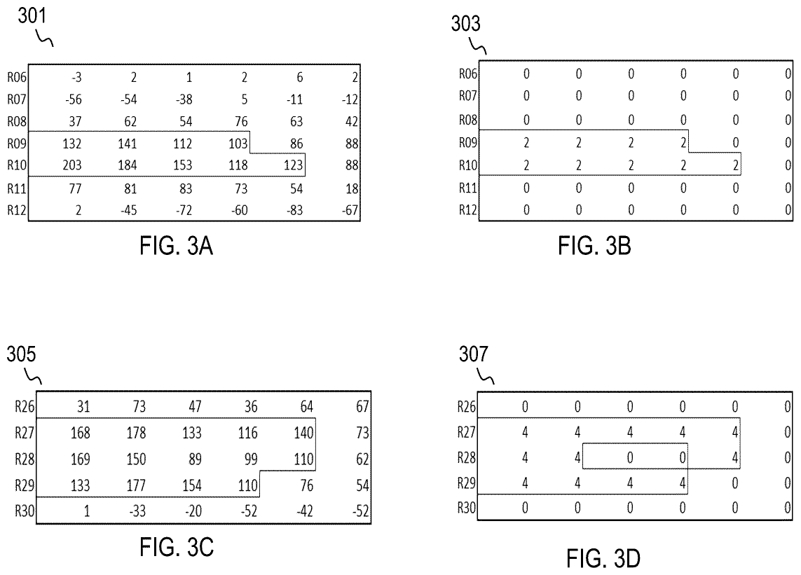

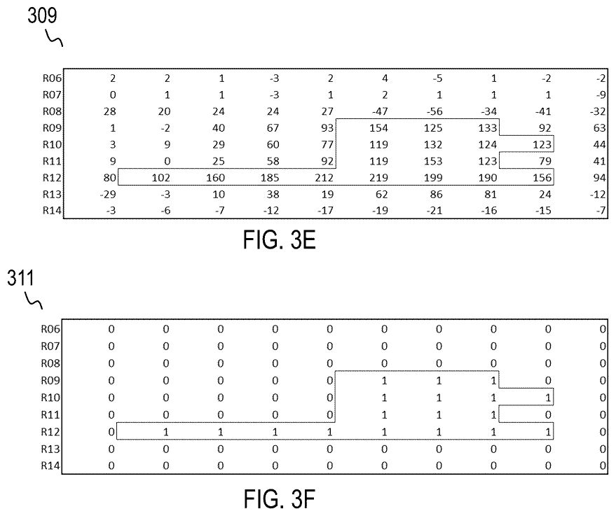

FIGS. 3A-3F illustrate external noise data and touch bitmaps of a touchscreen device according to an embodiment of the present application. FIGS. 3A-3F will be described in conjunction with FIGS. 1A-1B and 2A-2D. The external noise data 301, 305, 309 represent changes in capacitance detected on the touch sensing layer 116 of the touchscreen device 100 caused by ping signals transmitted by a wireless charger 200. The touch bitmaps 303, 307, 311 represent ghost touches that correspond to the external noise data 301, 305, 309 from the ping signals transmitted by the wireless charger 200.

The changes in capacitance may be caused by touch inputs from a user's finger or from a stylus, noise generated from images displayed on the touchscreen device, and external noise generated by various sources including wireless chargers, for example. In various embodiments, the strength of the change in capacitance that are greater than a touch detection threshold may be detected as touch inputs by the touch controller 104 and reported to the system on a chip 106 to perform an action on the touchscreen device 100. For example, the touch detection threshold may be a value of 100. When the strength of the change in capacitance is greater than 100, the touch controller 104 can interpret the changes in capacitance as a touch event.

FIG. 3A shows external noise data 301 collected from the touch sensing layer 116 of a touchscreen device 100. Referring to FIG. 3A, the external noise data 301 represents external noise interference from the ping signals transmitted by the wireless charger 200 without touch inputs. While the external noise data are not from touch inputs, the values of the external noise data 301 greater than a touch detection threshold can be interpreted as a touch event.

FIG. 3B shows a touch bitmap 303 that represents the touch events corresponding to the external noise data in FIG. 3A. The external noise data 301, where capacitive strength data is greater than a touch detection threshold, is shown on the touch bitmap 303 as positive touch values to indicate a location that the touchscreen controller 104 has registered a touch event from the ping signals of the wireless charger 200. The positive touch values represent the ghost touch points that appear on the screen when no actual finger touch is present due to the electromagnetic interference from the wireless charger's ping signals.

FIGS. 3C and 3D show another example of a ghost touch from ping signals transmitted by the wireless charger 200. FIG. 3C shows external noise data 305 that shows the capacitive strength data collected from the touch sensing layer 116 of the touchscreen device 100, and FIG. 3D shows a touch bitmap 307 that represents the touch events corresponding to the external noise data in FIG. 3C.

FIGS. 3E and 3F show another example of a ghost touch from ping signals transmitted by the wireless charger 200. FIG. 3E shows external noise data 309 that shows the capacitive strength data collected from the touch sensing layer 116 of the touchscreen device 100, and FIG. 3F shows a touch bitmap 311 that represents the touch events corresponding to the external noise data in FIG. 3E.

As shown in FIGS. 3A-3F, the touch events can form a variety of shapes from the ping signals transmitted by the wireless charger 200. In various embodiments, the variety of shapes can be used to determine an appropriate noise reduction measure to apply to mitigate external noise interference from the wireless charger 200. The touch events on the touch bitmaps 303, 307, 311 can form a variety of shapes from the ping signals transmitted by the wireless charger 200. The ping signals transmitted by the wireless charger may producing a variety of common shapes, for example, a long shape as shown in FIGS. 3E and 3F. In one or more embodiments, various predetermined shape filters that match a common shape generated by a wireless charger can be used as noise reduction measure. The various predetermined shape filters can be stored in memory 110 of the touch controller 104. For example, when the touch event on the touch bitmap forms a shape that matches a predetermined shape filter stored in the touch controller 104, the touch controller 104 can determine that the touch event is external noise data as opposed to a touch input. When the touch event is determined to be external noise data, the touch controller 104 does not report the touch event to the system on a chip (SoC).

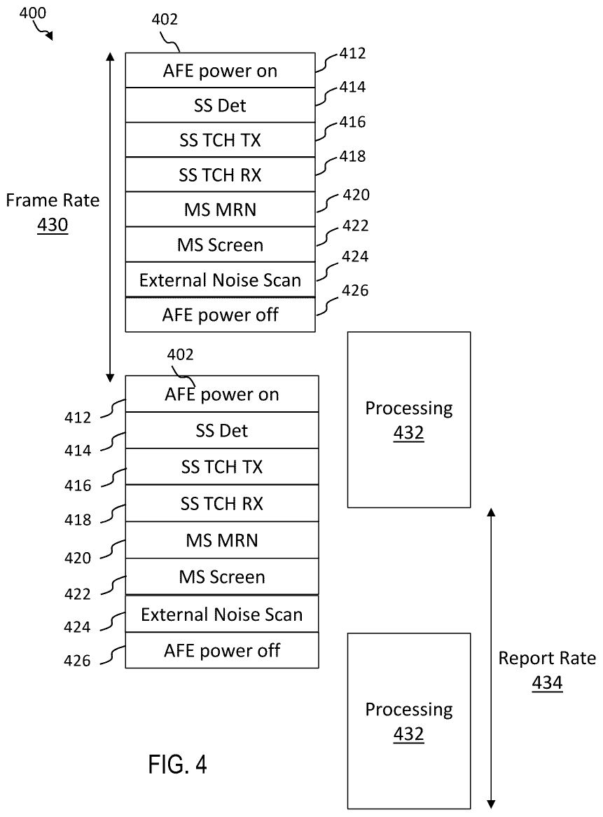

FIG. 4 illustrates a scanning process according to an embodiment of the present application. The scanning process 400 shows scanning sequences 402 and processing blocks 432. FIG. 4 will be described in conjunction with FIGS. 1A and 1B. It is understood, however, that the operations can be performed with other hardware.

In one or more embodiments, the touch controller 104 performs multiple scanning operations to detect and validate touch events on the touchscreen device 100. The touch controller 104 executes a scanning sequence 402 that includes powering on the analog front end (AFE) 412, performing self-sensing detection 414, performing self-sensing scans 416, 418, performing a noise monitoring scan 420, performing a mutual scan 422, performing an external noise scan 424 before powering off the AFE 426. The scanning sequence 402 can be performed for each frame to mitigate noise interference and perform touch detection. The scanning sequence 402 can be configured to balance factors such as power consumption, settling time of analog circuits, and frame timing requirements.

Each scanning sequence 402 begins with powering on the analog front end (AFE) circuit 412 (AFE power on). In various embodiments, AFE power on 412 represents an initial stage of each touch scanning frame where the analog circuitry required for touch sensing is energized and prepared for operation. The AFE contains the analog circuits used for driving signals onto the touch sensing electrodes and measuring received touch signals. During AFE power on 412, various analog components are activated in a controlled sequence. In one or more embodiments, the analog components can include drive signal generators, sensing amplifiers, analog filters, and analog-to-digital converters to perform for touch detection. The AFE power on sequence ensures proper initialization of analog circuits to achieve stable operating conditions before beginning touch scanning operations. In one or more embodiments, AFE power on 412 occurs at the start of each frame before self-sensing and mutual sensing operations can begin. In various embodiments, the timing of the AFE power on is coordinated with a frame rate 430 to maintain consistent scanning intervals.

Following AFE power on 412, self-sensing operations may be performed. In various embodiments, self-sensing operations represent a sequence of scanning steps performed by the touch controller 104 to detect touch inputs using self-capacitance measurements. In one or more embodiments, the self-sensing operations include initiating self-sensing detection 414 (SS Det), performing a self-sensing scan 416 on drive channels (SS TCH TX), and performing a self-sensing scan 418 on sense channels (SS TCH RX). The order of these operations is not necessarily as shown.

In one or more embodiments, the self-sensing detection 414 initiates the self-sensing sequence by preparing the touch controller 104 to measure changes in self-capacitance of individual electrodes. In various embodiments, self-sensing detection 414 includes preparing the analog circuits and digital control logic for self-capacitance measurements. Self-sensing detection 414 may also include setting up measurement parameters and reference levels used to identify potential touch activity.

In one or more embodiments, the self-sensing scan 416 on the drive channels involves driving signals onto each drive channel to enable self-capacitance measurements of the drive electrodes and ground. Similarly, the self-sensing scan 418 on the sense channels includes driving signals onto each sense channel to enable self-capacitance measurements of the sense electrodes and ground. Self-capacitance is an electrical capacitance between a single conductor and ground. In the touch sensing layer 116, the self-capacitance of a drive channel or sense channel can be measured independently of other drive and sense channels. The touch controller 104 can measure the change in self-capacitance of individual drive or sense channels. When a touch event occurs, the changes in the self-capacitance of the corresponding channel enables the detection of touch location.

In one or more embodiments, the self-sensing operations can complement the mutual scans by providing additional touch detection data using a different measurement technique. The combination of self-sensing and mutual scan measurements can help improve overall touch detection reliability, particularly in challenging noise environments.

Following the self-sensing scans 416, 418, the noise monitoring scan 420 (i.e., MS MRN) can be performed. The noise monitoring scan 420 can detect noise data on the touchscreen 102 (MS MRN). During the noise monitoring scan 420, the touch controller sets all drive channels (i.e., TX channels) to a high-impedance state or grounds them, effectively silencing active touch sensing elements. In this state, the sense channels (i.e., RX channels) remain active but are solely “listening” to the environment. Any signals detected on the sense channels may be categorized as noise, which can originate from various sources such as images on the display, power supplies, nearby touchscreen devices, or chargers and USB connections.

Following the noise monitoring scan 420, the mutual scan 422 (MS Screen) can be performed. The mutual scan can be used to collect capacitive strength data or changes in capacitive coupling on the touchscreen device 100. The mutual scan enables touch detection by measuring changes in the capacitive coupling between TX and RX electrodes across the entire touch sensing layer 116. When finger approaches the touchscreen 102, the electric field surrounding the sensing nodes are affected and reduces the coupling capacitance at the affected sensing nodes which can be used to determine a location or coordinates of a touch input. While the mutual scan 422 is typically performed after the noise monitoring scan 420, it is understood that the order can be reversed.

In one or more embodiments, the mutual scan 422 involves driving the drive channels sequentially to scan the touch sensing layer 116 while the sense channels measure the signals simultaneously to collect capacitive strength data measurements in parallel. The touch controller 104 can supply drive channels on the touch sensing layer with transmission signals at specific frequencies while the sense channels receive signals coupled through the sensing nodes formed at the sensing nodes. The capacitive strength data measurements can indicate a degree of coupling at each sensing node and indicate the presence of touch inputs. The capacitive strength data measurements can be used to create a two-dimensional strength bitmap of touch activity.

In one or more embodiments, the mutual scan 422 may be configured with specific scanning and processing configurations to detect touch inputs that can be adapted based on operating mode and noise conditions. The touch controller 104 may select an optimal frequency for performing the mutual scan 422 to minimize noise interference while collecting the capacitive strength data. In various embodiments, the touch controller 104 can analyze the noise data from the noise monitoring scan 420 and the capacitive strength data measurements from the mutual scan 422 across multiple frames to distinguish sustained touch events from transient noise spikes.

Following the mutual scan 422, the external noise scan 424 can be performed by enabling the Rx channels to collect external noise data at a specific sensing frequency without driving the TX channels. In various embodiments, the external noise scan 424 can be performed to detect the presence of external noise interference on the touchscreen device 100. In one or more embodiments, the external noise scan 424 can be used to collect external noise data on the touchscreen device 100 to determine whether ping signals from a wireless charger 200 are detected. In the external noise scan 424, the touch controller sets all drive channels (i.e., TX channels) to a high-impedance state or grounds them to silence the active touch sensing elements while the sense channels (i.e., RX channels) remain active to listen to the environment. The signals detected on the sense channels during the external noise scan 424 can be categorized as external noise.

In various embodiments, the touch controller 104 can perform the external noise scan 424 at a sensing frequency that corresponds to the frequency of signals from external devices that interfere with touch detection. For example, the external noise scan 424 can performed at a sensing frequency Freqo of 141 kHz, for example, that corresponds to the ping signals of a wireless charger 200.

In one or more embodiments, the external noise scan 424 can be performed at a plurality of different sensing frequencies Freqo, Freq1, Freq2 for each frame. For example, the different sensing frequencies Freqo, Freq1, Freq2 may be performed at 111.1 kHz, at 140.4 kHz, and 175.8 kHz, respectively. By performing the external noise scan 424 at multiple sensing frequencies, the touch controller 104 can analyze noise characteristics for different operating frequencies that interfere with touch detection from external device. While this example shows three different sensing frequencies, it is understood that two or more than three sensing frequencies can be scanned.

After the external noise scan 424, the scanning sequence 402 concludes by powering off the analog front end (AFE) circuit 426 (i.e., AFE power off). At the end of each frame, the AFE may be powered off to conserve power until the next frame begins. When the scanning sequence 402 is complete, the touch controller 104 begins processing 432 the external noise data and strength data measurements collected from the preceding scanning sequence 402. When processing 432 is complete for the preceding scanning sequence 402, the coordinates of the touch input on the touchscreen 102 can be reported to the system on a chip 106 at a report rate 434.

In one or more embodiments, the touch controller 104 can perform the next scanning sequence 402 while the touch controller 104 is processing 432 the preceding scanning sequence 402. The touch input may be reported to the system on a chip 106 while performing the next scanning sequence 402 and while processing 432 the next scanning sequence. The scanning sequence 402 can repeat continuously for each subsequent frame.

The scanning process 400 can be used to detect the presence of noise interference, apply appropriate noise reduction measures based on the presence of noise interference, and perform touch detection based on the applied noise reduction measures. The scanning process 400, such as the scanning frequencies in the scanning sequence 402, can be adapted to eliminate detected noise interference in touch detection, for example, by selecting specific scanning frequencies for the various scans in the scanning sequence 402.

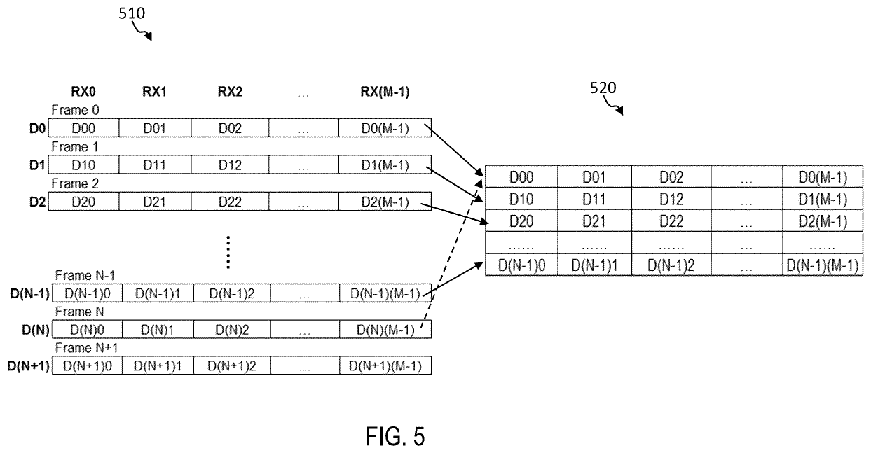

FIG. 5 illustrates storing external noise data for special scans according to an embodiment of the present application. FIG. 5 will be described in conjunction with the figures described above.

In one or more embodiments, the external noise scan 424 can be performed at a sensing frequency that corresponds to the frequency of signals from external devices, such as wireless chargers, that interfere with touch detection as described in FIG. 4. The external noise scan 424 can detect the external noise data for each RX channel (i.e., sense channel) at the selected sensing frequency Freqo for multiple frames or samples. For example, each external noise scan 424 collects a noise line 510 for the corresponding sensing frequency Freqo for each frame. Each line or row of noise data includes noise data for M number of sense channels. For example, the external noise scan 424 for Frame o at Freqo collects a line of noise data Doo, Do1, Do2, . . . , Do (M-1) for the sense channels Rxo, Rx1, Rx2, . . . , Rx (M-1) and Frame N-1 at Freqo collects a line of noise data D (N-1) 0, D (N-1) 1, D (N-1) 2, . . . , D (N-1) (M-1) for sense channels Rxo, Rx1, Rx2, . . . , Rx (M-1).

In one or more embodiments, the touch controller 104 can store the noise data in memory 110. In one or more embodiments, the noise data collected from the external noise scan 424 can be stored in a circular buffer 520. The circular buffer 520 can organize the noise data by a number of frames or samples of historical noise data measurements for the number of sense channels. As noise data from new frames are collected, the noise data from the new frame can replace the oldest noise data in the circular buffer 520 and maintain a rolling window of N frames or samples of historical external noise measurements from the external noise scan 424 for each sense channel.

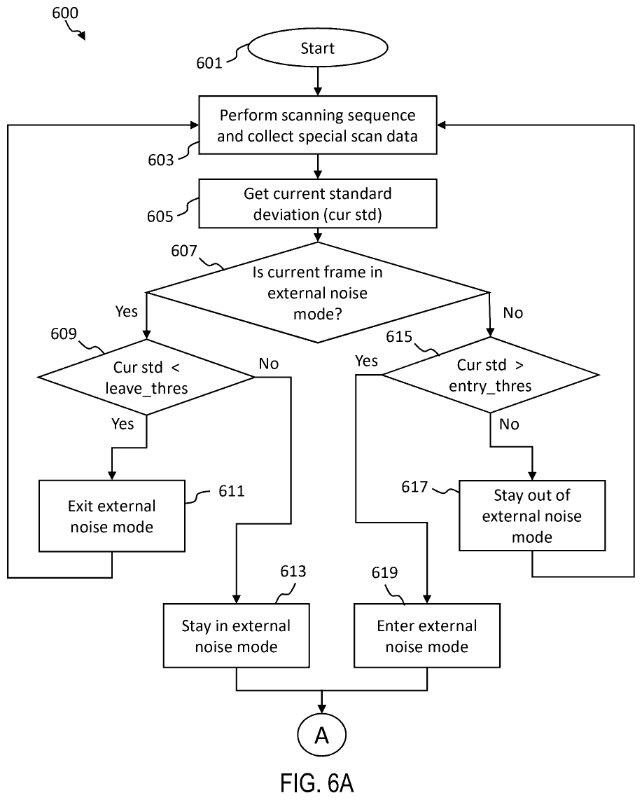

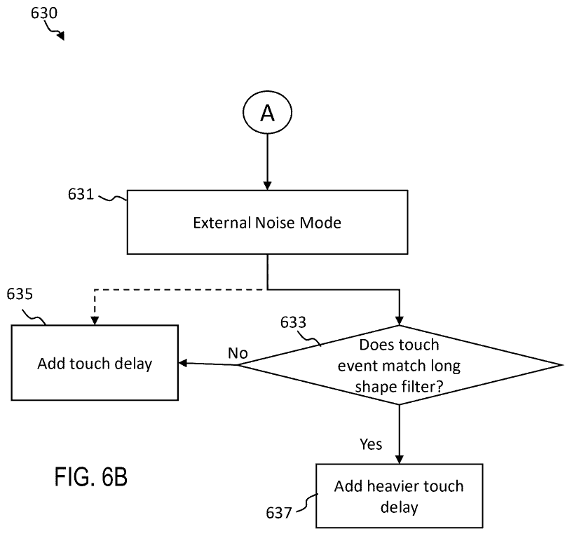

FIGS. 6A and 6B illustrate flowcharts for an external noise mode process according to embodiments of the present application. FIGS. 6A and 6B will be described in conjunction with the figures described above.

FIG. 6A shows a flowchart of a process 600 for detecting external noise in a touchscreen device 100. In one or more embodiments, the process 600 for detecting external noise can be configured to detect external noise from ping signals of a wireless charger 200. The process 600 begins at step 601. The process flows to step 603 to perform the scanning process 400 to collect external noise data from the external noise scan 424 for a plurality of frames or samples. The external noise data collected from the external noise scan 424 can be stored in memory 110 of the touch controller 104. For example, the collected external noise data may be stored in a first-in-first-out (FIFO) buffer that is updated for every frame as described in FIG. 5.

In step 605, the touch controller 104 can execute instructions to calculate a current standard deviation (cur std) from the collected external noise data in step 603. The current standard deviation can be used to determine whether the touchscreen device 100 is operating in an external noise mode and when to operate in external noise mode. In various embodiments, external noise mode can be used when external noise interference is present. In one or more embodiments, the external noise mode can be used to mitigate noise interference, for example, when a wireless charger 200 is in proximity to the touchscreen device 100.

In one or more embodiments, the current standard deviation (cur std) is calculated based on a standard deviation stddevⱼ. The standard deviation stddevⱼ is a standard deviation of the collected external noise data for each sense channel across the N frames for the sensing frequency of a special scan. The standard deviation of the external noise data can be calculated based on the external noise data for the sense channel Dᵢⱼ and an average of the external noise data for each sense channel Avgj. For example, the average of the external noise data across the N frames for sense channel Rxo is Avgₒ and the average of the external noise data across the N frames for sense channel Rx (M-1) is Avg (M-1).

In one or more embodiments, the standard deviation stddevⱼ for each sense channel can be calculated using the equation:

$${stddev}_{j} = \frac{1}{N} {Σ}_{i = 0}^{N - 1} \vert {D}_{ij} - A v {g}_{j} \vert ,$$

where i is a sample number (e.g., o to N-1), j is the sense channel (e.g., Rxo to Rx (M-1)), D is the external noise data stored for the corresponding sample i and sense channel j, and N is a number of frames or samples. For example, the standard deviation of external noise data for 16 frames for sense channel Rxo can be calculated using the equation:

$${stddev}_{0} = \frac{1}{16} {Σ}_{i = 0}^{15} \vert {D}_{i 0} - {Avg}_{0} \vert .$$

In one or more embodiments, the current standard deviation (cur std) for the sensing frequency is determined based on a maximum standard deviation of the standard deviation stddevᵢ. The maximum standard deviation can be calculated using the equation:

cur std=max(stddev₀,stddev₁,stddev₂, . . . ,stddev_{(M-1)}).

In one or more embodiments, a current standard deviation (cur std) can be determined for each of the multiple sensing frequencies Freqo, Freq1, Freq2. For example, when the external noise scan 424 is performed at three different special scan frequencies Freqo, Freq1, Freq2, a first current standard deviation (cur std) is determined based on the maximum standard deviation for Freqo, a second current standard deviation (cur std) is determined based on the maximum standard deviation for Freq1, and a third current standard deviation (cur std) is determined based on the maximum standard deviation for Freq2.

In one or more embodiments, a current standard deviation (cur std) having a small value can indicate that the external noise data is relatively stable and the distribution across the sensing nodes is concentrated on an area of the touch sensing layer 116. In one or more embodiments, a current standard deviation (cur std) having a large value can indicate volatility or uncertainty in the external noise data and the external noise data is dispersed across the sensing nodes.

In step 607, the touch controller 104 determines whether the current frame is in external noise mode. When the touchscreen device 100 is operating in external device noise mode (i.e., 607=Yes), the process moves to step 609 to determine whether the current standard deviation is less than a predetermined leave threshold (leave_thres). When the current frame is not in external device noise mode (i.e., 607=No), the process proceeds to step 615 to determine whether the current standard deviation exceeds a predetermined entry threshold (entry_thres). In one or more embodiments, the predetermined leave threshold and the predetermined entry threshold can be a threshold set to a same value. For example, the predetermined leave threshold and the predetermined entry threshold may be set to the same value for multiple sensing frequencies, for example, at 175.8 kHz, 140.4 kHz, and 111.1 kHz. In other embodiments, the predetermined leave threshold and predetermined entry threshold may be set to different values. For example, the predetermined leave threshold maybe set to 100 and the predetermined entry threshold may be set to 1000 for a sensing frequency at 140.4 kHz.

When the touchscreen device 100 is operating in external device noise mode (i.e., 607=Yes) and the current standard deviation is less than the predetermined leave threshold (i.e., 609=Yes), the touch controller 104 exits external noise mode in step 611. When the current frame is not in external device noise mode (i.e., 607=No), and the current standard deviation is less than the predetermined entry threshold (i.e., 615=No), the touch controller 104 remains out of external noise mode in step 617. In one or more embodiments, when the touchscreen device 100 exits the external noise mode in step 611 or is not in external noise mode in step 617, the process returns to step 603 to begin the next scanning process 400.

When the touchscreen device 100 is operating in external device noise mode (i.e., 607=Yes) and the current standard deviation is greater than the predetermined leave threshold (i.e., 609=No), the touch controller 104 remains in external noise mode in step 613. When the touchscreen device 100 is not operating in external device noise mode (i.e., 607=No) and the current standard deviation is greater than the predetermined entry threshold (i.e., 615=Yes), the touch controller 104 enters external noise mode in step 619. When the touchscreen device 100 is operating in external device mode, noise reduction measures for external noise interference can be applied as described in below in an external noise mode process 630 shown in FIG. 6B.

FIG. 6B shows a flowchart of an external noise mode process 630 in a touchscreen device 100. When the touchscreen device 100 stays in the external noise mode in step 613 or enters the external noise mode in step 619 of FIG. 6A, the process flows to external noise mode in step 631 to determine the appropriate noise reduction measures to apply in order to mitigate external noise interference.

In one or more embodiments, the process 630 continues to step 633 to determine whether the touch event matches a long shape filter, as described in FIGS. 3A-3F. When the touch event on the touch bitmap forms a shape that does not match the long shape filter (e.g., 635=No), the process continues to step 635 to add a touch delay. When the touch event on the touch bitmap forms a shape that matches the long shape filter (e.g., 633=Yes), the process continues to step 637 to add a heavy touch delay that includes more multiple consecutive frames, e.g., 5 to 10 additional frames, than the touch delay in step 635. In some embodiments, the process 630 can be simplified and continue directly to step 635 to add a touch delay when operating in external noise mode.

Touch delay is a noise reduction measure that can improve touch detection by reporting capacitive strength data that is present for consecutive frames as a touch input. Noise interference signals are typically random and transient between frames whereas touch inputs are typically stable and consistent for multiple consecutive frames. In one or more embodiments, touch delay involves determining whether capacitive strength data occur near the same coordinates on the touch panel for multiple consecutive frames and processing the capacitive strength data as a touch input when it is present on a subsequent frame. For example, when the capacitive strength data is present near the same coordinates for multiple frames N, N+1, N+2, the touch controller processes the capacitive strength data corresponding to the changes in capacitance on the subsequent frame N+2 as a touch input.

In one or more embodiments, the capacitive strength data may be near the same coordinates on a touch panel when a coordinate gap between two frames is within a number of pixels. For example, the number of pixels for the coordinate gap may be 150 pixels on a touch panel that is 2400×2200 pixels (i.e., 160 mm×74 mm). As another example, when the touch delay is set for three frames and the capacitive strength data coordinates of four frames are, e.g., (100, 100), (120, 130), (80, 90), and (110, 120), the coordinate gaps between each of two adjacent frames are determined to be within 150 pixel, the capacitive strength data occurs on four consecutive frames and the coordinates of the fourth frame (110, 120) can be processed and reported as a touch input.

In one or more embodiments, touch delay can be performed by analyzing the external noise data 301, 305, 309 or the touch bitmaps 303, 307, 311 for multiple consecutive frames. When capacitive strength data on the sensing nodes overlap for multiple consecutive frames, the touch controller 104 can determine that a touch input is present at the overlapping sensing nodes and the touch input can be reported as a touch event. For example, the touch controller 104 can determine that the capacitive strength data on the sensing nodes is a touch input when the changes in capacitance occur on the same sensing nodes are observed on multiple frames (e.g., frame N, N+1, or N+n).

While the touch input may be detected on a first frame N, with touch delay, the touch controller 104 reports the touch event when the touch input is detected on a later frame (e.g., N+1, N+2, or N+n). For example, with touch delay added in step 635, the touch controller 104 can be configured to report the touch event on frame N+2 when the touch input is present on the same sensing nodes for frames N, N+1, and N+2, and with the heavy touch delay added in step 637, the touch controller 104 may be configured to report the touch event on frame N+4 when the touch input is present on the same sensing nodes for frames N, N+1, N+2, N+2, N+3, and N+4. The specific frame used for touch delay can vary for different devices or projects.

The processes 600, 630 enable the touch controller 104 to determine the presence of wireless charger interference and apply appropriate noise reduction measures to maintain normal touch functionality while eliminating ghost touches caused by ping signals from the wireless charger.

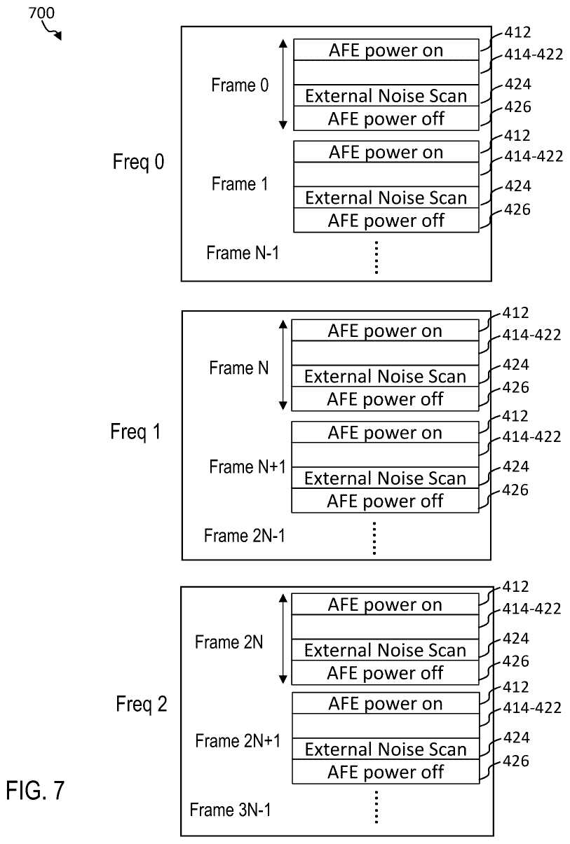

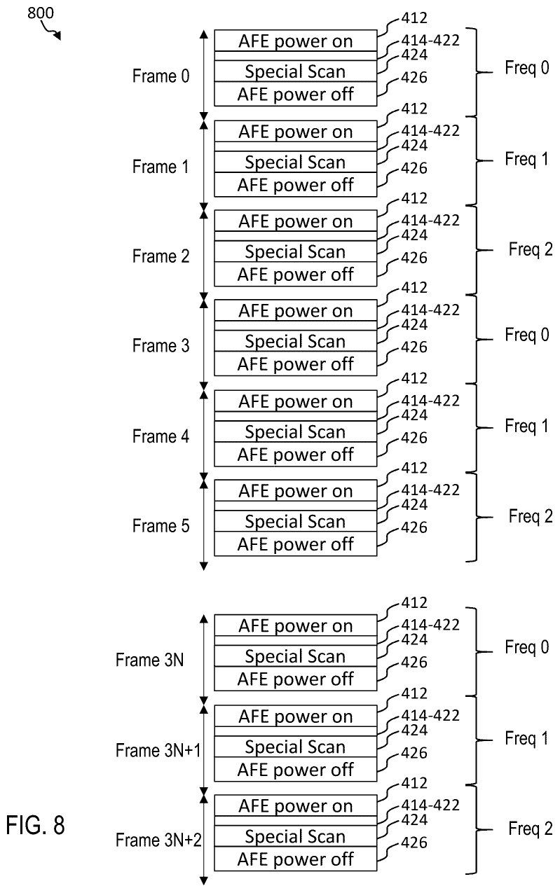

FIGS. 7 and 8 illustrate scanning processes according to an embodiment of the present application. FIGS. 7 and 8 will be described in conjunction with the figures described above.

FIGS. 7 and 8 shows scanning processes for multiple sensing frequencies to detect external noise data from wireless chargers across different frequency bands. The scanning sequence in FIGS. 7 and 8 show a condensed version of the scanning sequence 402 shown in FIG. 4. The condensed scanning sequence shows powering on the analog front end (AFE) 412, performing an external noise scan 424, and powering off the AFE 426 as described in FIG. 4. While the frame rate 430, processing block 432, and report rate 434 are not shown here, it is understood that the scanning processes also includes a frame rate, processing time, and report rate.

Also as described in FIG. 4, the external noise scan 424 can be performed to detect the presence of external noise interference on the touchscreen device 100. In one or more embodiments, the external noise scan 424 can be used to collect external noise data on the touchscreen device 100 to determine whether ping signals from a wireless charger 200 are detected.

Referring to FIG. 7, the external noise scan 424 in the scanning process 700 can be performed for a plurality of frames at each of the of the multiple sensing frequencies Freqo, Freq1, Freq2 to detect external noise data. When the scanning sequence for the plurality of frames is complete at a first sensing frequency, a scanning sequence at the next sensing frequency can begin. For example, the scanning sequence can be performed at a first sensing frequency Freqo for Frame o, a second sensing frequency Freq1 for Frame N, and a third sensing frequency Freq2 for Frame 2N. In one or more embodiments, the external noise scan 424 of the scanning process 700 can be performed at a first sensing frequency Freqo for a first set of frames (e.g., o to N-1 frames), performed at a second sensing frequency Freq1 for a second set of frames (e.g., N to 2N-1 frames), and performed at a third sensing frequency Freq2 for a third set of frames (e.g., 2N to 3N-1 frames). For example, when the scanning process 700 is configured to collect 16 frames or samples of data from the touchscreen device 100 for each sensing frequency, the external noise scan 424 can be performed at the first sensing frequency Freqo for frames o to 15, the second sensing frequency Freq1 for frames 16 to 31, and the third sensing frequency Freq2 for frames 32 to 47.

Referring to FIG. 8, the external noise scan 424 in the scanning process 800 can be performed at each of the of the multiple sensing frequencies Freqo, Freq1, Freq2 on each of the plurality of frames. When the scanning sequence for a first frame at a first sensing frequency is complete, the scanning sequence for the next frame at the next sensing frequency can begin. In one or more embodiments, the external noise scan 424 in the scanning process 800 can be performed at a first sensing frequency Freqo for a first frame, a second sensing frequency Freq1 for a second frame, then a third sensing frequency Freq2 for a third frame, and so on. For example, the external noise scan 424 can be performed at the first sensing frequency Freqo for frame o, the second sensing frequency Freq1 for frame 1, the third sensing frequency Freq2 for frame 2, the first sensing frequency Freqo for frame N, the second sensing frequency for frame N+1, the third sensing frequency for frame 2N-1, and so on.

In one or more embodiments, the scanning processes 700, 800 collect external noise data by performing the external noise scan 424 at multiple sensing frequencies Freqo, Freq1, Freq2 over multiple frames N. The external noise scan 424 can be tuned to multiple sensing frequencies Freqo, Freq1, Freq2 corresponding to the common wireless charger ping signal frequencies that can interfere with touch detection and touchscreen functionality. For example, the touch controller 104 can be tuned to perform the external noise scan 424 at 175.8 kHz (for the 170-180 kHz range) for Freqo, 140.4 kHz (for the 135-145 kHz range) for Freq1, and 111.1 kHz for Freq 2, based on standard wireless charger protocols.

In one or more embodiments, the external noise data collected for the multiple sensing frequencies from scanning processes 700, 800 can be stored in memory 110 of the touch controller 104. The external noise data for the multiple sensing frequencies Freqo, Freq1, Freq2 can be used to determine whether the touchscreen device 100 is in proximity to a wireless charger as described in FIG. 6A and whether to operate in external noise mode to apply noise reduction measures described in FIG. 6B. By collecting external noise data for multiple sensing frequencies, the touchscreen device 100 can detect interference from various types of wireless chargers with different operating frequencies.

The scanning processes 700, 800 of FIG. 7 and FIG. 8 provide different scanning configurations for collecting external noise data for multiple sensing frequencies corresponding to wireless charger protocols. In one or more embodiments, the scanning process 700 of FIG. 7 can be used to detect external noise for multiple sensing frequencies in step 603 of FIG. 6A. In other embodiments, the scanning process 800 of FIG. 8 can be used to detect external noise for multiple sensing frequencies in step 603 of FIG. 6A While this example shows three different sensing frequencies, it is understood that two sensing frequencies or more than three sensing frequencies can be used for the external noise scan 424.

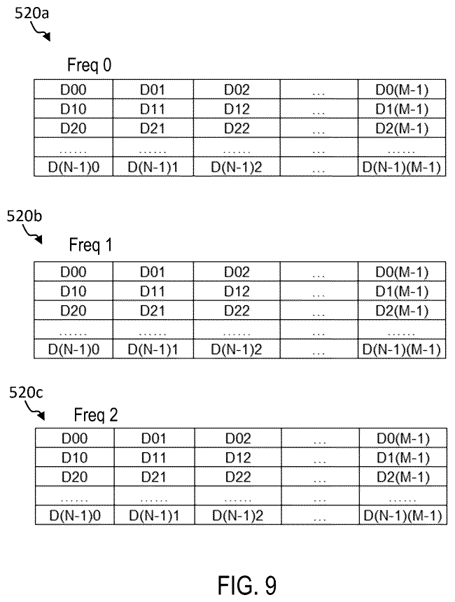

FIG. 9 illustrates storing external noise data of a special scan according to an embodiment of the present application. FIG. 9 will be described in conjunction with the figures described above.

FIG. 9 shows circular buffers 520a, 520b, 520c external noise data collected from the external noise scan 424 for each frame at multiple sensing frequencies Freqo, Freq1, Freq2 as described in FIGS. 7 and 8. In one or more embodiments, the touch controller 104 can store the external noise data in circular buffers 520a, 520b, 520c in memory 110 of the touch controller 104. The circular buffers 520a, 520b, 520c can store external noise data collected from different scanning approaches, such as scanning at each sensing frequency for N consecutive frames before moving to the next frequency as described in FIG. 7, or cycling through all sensing frequencies on a frame-by-frame basis as described in FIG. 8.

In one or more embodiments, the circular buffers 520a, 520b, 520c may be first-in-first-out buffers or FIFO buffers. The circular buffers 520a, 520b, 520c can organize the external noise data by sensing frequency (e.g., Freqo, Freq1, Freq2) and a number of frames or samples (e.g., N frames) of historical external noise data measurements for the number of sense channels (e.g., M sense channels). For example, the external noise data for each of the sensing frequencies can be stored in a FIFO buffer having a size of N×M, where N is the sample size and M is the number of sense channels. As external noise data from new frames are collected, the external noise data can replace the oldest external noise data in the corresponding circular buffers 520a, 520b, 520c and maintain a rolling window of N frames or samples of historical external noise measurements for each sensing frequency and sense channel.

In one or more embodiments, each cell in the circular buffers 520a, 520b, 520c stores external noise data corresponding to a sensing frequency, frame, and sense channel. For example, in the circular buffers 520a, 520b, 520c, cell Doo represents external noise data that corresponds to sensing frequency Freqo, Frame #0,and sense channel Rxo, and cell D10 represents external noise data that corresponds to sensing frequency Freqo, Frame #1 and sense channel Rxo. Each line of external noise data can be stored in a circular buffers 520a, 520b, 520c for each sensing frequency by frame. For example, the first line of data stored in the circular buffer 520a corresponds to the sensing frequency Freqo for Frame #0, the second line of data stored corresponds to sensing frequency Freqo for Frame #1, and so on. When the circular buffer 520a is full, the external noise data corresponding sensing frequency Freqo for the newest frame, for example, Frame #16 can overwrite the stored external noise data for Frame #0 in the circular buffer 520a. While this example describes the external noise data stored in circular buffer 520a for Freqo, it is understood that the external noise data is stored similarly in circular buffer 520b for Freq1 and circular buffer 520c for Freq2.

In various embodiments, the circular buffers 520a, 520b, 520c can maintain 16 frames or samples of historical external noise data measurements for each sensing frequency. By storing the historical external noise measurements for each sensing frequency, the touch controller 104 can perform statistical analysis of noise patterns across both time and frequency domains. For example, standard deviation calculations across the N frames or samples of external noise data measurements can allow the touch controller 104 to determine whether noise interference from ping signals of a wireless charger is present. Based on the standard deviation calculations, the touch controller 104 can enter an external noise mode to apply noise reduction measures to mitigate the noise interference caused by ping signals of the wireless charger 200.

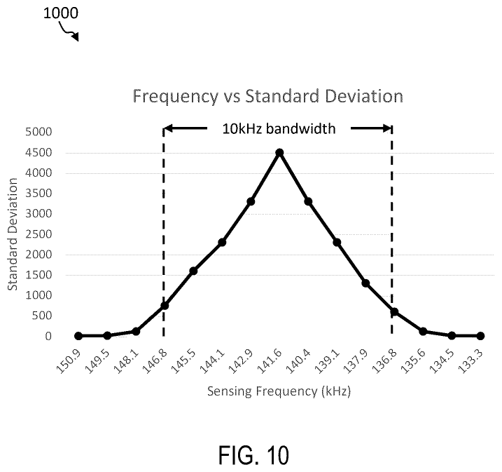

FIG. 10 illustrates a graph showing a relationship between sensing frequencies and standard deviations according to embodiments of the present application. FIG. 10 will be described in conjunction with figures above.

FIG. 10 shows a relationship between sensing frequencies and standard deviations calculated from the external noise data collected from special scans 424. The standard deviations indicate the presence of noise interference from a wireless charger 200 at corresponding sensing frequencies. In one or more embodiments, the relationship between sensing frequencies and standard deviations can be used to determine the sensing frequency to use for an external noise scan 424 to detect the presence of noise interference from the wireless charger 200.

The graph 1000 shows example standard deviations for different sensing frequencies when a wireless charger having ping signal frequencies at 141.7 kHz is in proximity to the touchscreen device 100. As shown in graph 1000, the peak standard deviation 4500 is calculated from an external noise scan 424 performed at a sensing frequency of 141.7 kHz that matches the ping signal frequency of the wireless charger 200. The standard deviation values decrease as the sensing frequency increases or decreases from the ping signal frequency of the wireless charger 200.

In one or more embodiments, the standard deviation can indicate noise interference when the standard deviation is greater than a threshold value, for example, 600. As shown in FIG. 10, the standard deviation is greater than 600 for sensing frequencies between 136.8 kHz and 146.8 kHz or within a 10 kHz bandwidth of the ping signal frequency 141.7 kHz. In various embodiments, the standard deviation corresponding to the 10 kHz bandwidth can be used to set the predetermined leave threshold and predetermined entry threshold for steps 609 and 615 described in FIG. 6A. For example, the predetermined leave threshold and the predetermined entry threshold may be set to 600 for wireless chargers having a ping signal frequency of 141.7 kHz.

In one or more embodiments, the touch controller 104 can perform the special scans 424 at multiple sensing frequencies that corresponds to multiple ranges of sensing frequencies within a 10 kHz bandwidth for various wireless chargers. The multiple sensing frequencies can be used to tune the sensing frequencies for special scans 424 to detect noise interference from ping signals of various wireless chargers. For example, wireless charger protocols can include ping signal frequencies in a range of 170 kHz to 180 kHz according to MP-A1 power transmitter standard protocol, 135 kHz to 145 kHz according to MP-A2 power transmitter standard protocol, and 111 kHz according to MP-A12 power transmitter standard protocol. For this example, the sensing frequencies can be tuned to 175.8 kHz, 140.4 kHz, and 111.1 kHz to detect external noise interference from various wireless chargers using any of the MP-A1, MP-A2, or MP-A12 wireless charger protocols.

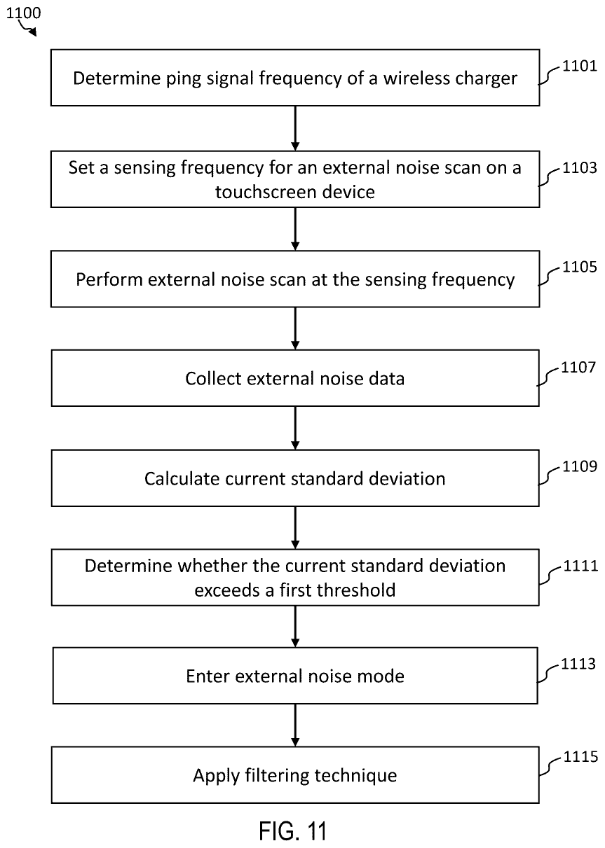

FIG. 11 illustrates a flowchart of a method for detecting and filtering wireless charger noise according to embodiments of the present application. FIG. 11 will be described in conjunction with figures above.

FIG. 11 illustrates a flowchart 1100 of a method for detecting and filtering external noise data from a wireless charger 200 on a touchscreen device 100. The process begins at step 1101 to determine a ping signal frequency of a wireless charger. In one or more embodiments, the ping signal frequency can be determined based on an operating frequency of a wireless charger or wireless charging protocols. The wireless charger 200 may operate at standard frequencies such as 111 kHz, 135-145 kHz, or 170-180 kHz based on the wireless charging protocol being used. In other embodiments, the ping signal frequency can be determined by detecting the ping signal frequency from a wireless charger.

Following step 1101, the flowchart 1100 proceeds to step 1103 to set a sensing frequency for an external noise scan 424 on the touchscreen device 100. The sensing frequency can be tuned to the ping signal frequency of the wireless charger 200 in step 1101. In one or more embodiments, the wireless charger 200 includes a range of operating frequencies and transmit ping signals within the range of operating frequencies. In one or more embodiments, the sensing frequency can be set to one of the ping signal frequencies within the range of operating frequencies. In some embodiments, the sensing frequency can be set to include multiple ping signal frequencies.

The flowchart 1100 proceeds to step 1105 to performs the external noise scan at the set sensing frequency. In one or more embodiments, the external noise scan is performed by enabling only the RX channels of the touchscreen to collect external noise data from each frame, without transmitting any charge signals from the TX channels. In one or more embodiments, the external noise scan can be performed using different sensing frequencies for different frames.

The flowchart 1100 continues to step 1107 to collects external noise data from the external noise scan 424. In one or more embodiments, the collected external noise data is stored in a circular buffer 520 or FIFO buffer. For example, each frame of collected external noise data can be stored as a row or line of data in the FIFO buffer as described in FIGS. 5 and 9.

The flowchart 1100 proceeds to step 1109 to calculates a current standard deviation from the collected external noise data. In one or more embodiments, the current standard deviation is calculated based the collected external noise data stored in the current frame and in past frames in the circular buffer. As described in FIG. 6A, the current standard deviation can be calculated using the equations: cur std=max (stddevₒ, stddev₁, stddev₂, . . . , stddevⱼ), where

$${stddev}_{j} = \frac{1}{N} {Σ}_{i = 0}^{N - 1} \vert {D}_{ij} - A v {g}_{j} \vert ,$$

where i is a sample number (e.g., o to N-1), j is the sense channel (e.g., Rxo to Rx (M-1)), D is the external noise data stored for the corresponding sample i and sense channel j, and Nis a number of frames or samples.

The flowchart 1100 proceeds to step 1111 to determine whether the current standard deviation exceeds a first threshold. In one or more embodiments, the first threshold value can be predetermined based on testing and calibration to ensure detection for a wide range of ping signal frequencies corresponding to wireless chargers. In one or more embodiments, the first threshold is a predetermined entry threshold for external noise mode as described in FIG. 6A. In one or more embodiments, the external noise data indicates noise interference from a wireless charger 200 when the current standard deviation exceeds the first threshold.

The flowchart 1100 proceeds to step 1113 to enters external noise mode when the current standard deviation exceeds the threshold. In one or more embodiments, the external noise mode is configured to apply appropriate noise reduction measures or filtering techniques to mitigate ghost touches caused by the presence of noise interference from wireless chargers 200. In one or more embodiments, the external noise mode performs the steps described in FIG. 6B.

Finally, the flowchart 1100 proceeds to step 1115 to apply the appropriate filtering techniques to mitigate the effects of the noise interference caused by the wireless charger 200. In one or more embodiments, the filtering technique includes adding a touch delay for reporting touch inputs, applying a heavy touch delay that includes more consecutive frames when the external noise data matches certain shape or patterns, or implementing other methods to reduce ghost touches when the external noise data indicates that the noise interference is caused by a wireless charger or an external device.

Embodiments of the present application enable touchscreen devices to detect noise interference caused by wireless chargers and mitigate the effects of the noise interference to maintain touch functionality when a touchscreen device is placed in proximity to a wireless charger.

Example embodiments of the present application are summarized here. Other embodiments can also be understood from the entirety of the specification and the claims filed herein.

Example 1. A first example comprises a method that includes setting a sensing frequency for an external noise scan on a touchscreen device to a ping signal frequency corresponding to a wireless charger, performing the external noise scan at the sensing frequency, collecting external noise data from the external noise scan, calculating a current standard deviation from the collected external noise data, determining whether the current standard deviation exceeds a first threshold, in response to the current standard deviation exceeding the first threshold, entering an external noise mode, and applying a filtering technique in response to being in the external noise mode.

Example 2. The method of example 1, where applying the filtering technique includes adding a touch delay for reporting touch inputs.

Example 3. The method of example 1 or 2, where applying the filtering technique includes determining whether the external noise data forms a predetermined shape, and in response to the external noise data forming the predetermined shape, adding a heavy touch delay.

Example 4. The method of any one of examples 1-3, where the method further includes detecting the ping signal frequency from the wireless charger to set the sensing frequency for the external noise scan.

Example 5. The method of any one of examples 1-4, where performing the external noise scan includes enabling RX channels.

Example 6. The method of any one of examples 1-5, where the method further includes storing the collected external noise data for each frame in a FIFO buffer having a size of N×M, wherein N is a sample size and M is a number of sense channels.

Example 7. The method of any one of examples 1-6, where performing the external noise scan at the sensing frequency includes performing the external noise scan at the ping signal frequency of 111 kHz or in a range of 135-145 kHz or 170-180 kHz.

Example 8. The method of any one of examples 1-7, where calculating the current standard deviation from the collected external noise data includes calculating an average of the external noise data of N frames for each sense channel, calculating standard deviations for each sense channel based on the external noise data and the average of the external noise data for the corresponding sense channel, and determining a maximum standard deviation from the standard deviations for each of the sense channels.

Example 9. The method of any one of examples 1-8, where the method further includes determining that the touchscreen device is in the external noise mode, in response to being in the external noise mode, determining whether the current standard deviation is less than the first threshold, in response to the current standard deviation being greater than the first threshold, remaining in the external noise mode, and in response to the current standard deviation being less than the first threshold, exiting the external noise mode.

Example 10. The method of any one of examples 1-9, where the method further includes determining that the touchscreen device is not in the external noise mode, in response to the touchscreen device not being in the external noise mode, determining whether the current standard deviation is greater than a second threshold, and in response to the current standard deviation being greater than the second threshold, entering the external noise mode.

Example 11. A method that includes performing external noise scans at a plurality of sensing frequencies corresponding to ping signal frequencies of wireless chargers, collecting external noise data from the external noise scans for each of the plurality of sensing frequencies, calculating a current standard deviation for each of the plurality of sensing frequencies from the collected external noise data, determining whether the current standard deviation for each of the sensing frequencies exceeds a threshold, and in response to the current standard deviation exceeding the threshold, entering an external noise mode.

Example 12. The method of example 11, where entering the external noise mode includes adding a touch delay for reporting touch inputs.

Example 13. The method of example 11 or 12, where entering the external noise mode includes determining whether the external noise data on a current frame forms a predetermined shape, in response to the external noise data not forming the predetermined shape, adding a touch delay for reporting touch inputs, and in response to the external noise data forming the predetermined shape, adding a heavy touch delay for reporting the touch inputs, wherein the heavy touch delay includes reporting the touch inputs after more consecutive frames than the touch delay.

Example 14. The method of any one of examples 11-13, where the method further includes detecting the ping signal frequencies from a plurality of wireless chargers to set as the sensing frequencies for the external noise scans.

Example 15. The method of any one of examples 11-14, where performing the external noise scans at the plurality of sensing frequencies includes performing a first external noise scan for a first frame at a first sensing frequency, performing a second external noise scan for a second frame at a second sensing frequency, and performing a third external noise scan for a third frame at a third sensing frequency.

Example 16. The method of any one of examples 11-15, where the first sensing frequency is 175.8 kHz, the second sensing frequency is 140.4 kHz, and the third sensing frequency is 111.1 kHz.

Example 17. The method of any one of examples 11-16, where the first frame, the second frame, and the third frame are non-consecutive frames.

Example 18. The method of any one of examples 11-17, where the method further includes storing the collected external noise data corresponding to each of the plurality of sensing frequencies in a corresponding FIFO buffer having a size of N×M, wherein N is a sample size and M is a number of sense channels.

Example 19. The method of any one of examples 11-18, where calculating the current standard deviation for each of the plurality of sensing frequencies from the collected external noise data includes calculating an average of the external noise data of N frames for each sense channel for each of the sensing frequencies, calculating standard deviations for each sense channel for each of the sensing frequencies based on the external noise data for each of the sensing frequencies and the average of the external noise data for the corresponding sense channel, and determining a maximum standard deviation for each of the sensing frequencies from the standard deviations for each sense channel.

Example 20. A device that includes a touchscreen, a touchscreen controller, and a non-transitory memory storing a program to be executed by the touch controller, the program including instructions to perform an external noise scan at a ping signal frequency of an electronic device for a plurality of frames, collect external noise data from the external noise scan for each frame of the plurality of frames, store the collected external noise data for each frame in a FIFO buffer, determine a standard deviation for a current frame from the stored external noise data in the FIFO buffer, determine whether the standard deviation for the current frame is greater than a threshold, and operate in an external noise mode in response to the standard deviation in the current frame exceeding the threshold.

Example 21. The device of example 20, where, when operating in the external noise mode, the program includes instructions to determine whether the external noise data on the current frame has a predetermined shape, in response to the external noise data not having the predetermined shape, add a touch delay for reporting touch inputs, and in response to the external noise data having the predetermined shape, add a heavy touch delay for reporting touch inputs, wherein the heavy touch delay includes more frames than the touch delay.

Example 22. The device of example 20 or 21, where the program includes instructions to perform the external noise scan at the ping signal frequency of 111 kHz or in the range of 135-145 kHz or 170-180 kHz.

While this application has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method comprising:
setting a sensing frequency for an external noise scan on a touchscreen device to a ping signal frequency corresponding to a wireless charger;
performing the external noise scan at the sensing frequency;
collecting external noise data from the external noise scan;
calculating a current standard deviation from the collected external noise data;
determining whether the current standard deviation exceeds a first threshold;
in response to the current standard deviation exceeding the first threshold, entering an external noise mode; and
applying a filtering technique in response to being in the external noise mode.

2. The method of claim 1, wherein applying the filtering technique comprises adding a touch delay for reporting touch inputs.

3. The method of claim 1, wherein applying the filtering technique comprises:
determining whether the external noise data forms a predetermined shape; and
in response to the external noise data forming the predetermined shape, adding a heavy touch delay.

4. The method of claim 1, wherein the method further comprises detecting the ping signal frequency from the wireless charger to set the sensing frequency for the external noise scan.

5. The method of claim 1, wherein performing the external noise scan comprises enabling RX channels.

6. The method of claim 1, wherein the method further comprises storing the collected external noise data for each frame in a FIFO buffer having a size of N×M, wherein N is a sample size and M is a number of sense channels.

7. The method of claim 1, wherein performing the external noise scan at the sensing frequency comprises performing the external noise scan at the ping signal frequency of 111 kHz or in a range of 135-145 kHz or 170-180 kHz.

8. The method of claim 6, wherein calculating the current standard deviation from the collected external noise data comprises:
calculating an average of the external noise data of N frames for each sense channel;
calculating standard deviations for each sense channel based on the external noise data and the average of the external noise data for the corresponding sense channel; and
determining a maximum standard deviation from the standard deviations for each of the sense channels.

9. The method of claim 8, wherein the method further comprises:
determining that the touchscreen device is in the external noise mode;
in response to being in the external noise mode, determining whether the current standard deviation is less than the first threshold;
in response to the current standard deviation being greater than the first threshold, remaining in the external noise mode; and
in response to the current standard deviation being less than the first threshold, exiting the external noise mode.

10. The method of claim 8, wherein the method further comprises:
determining that the touchscreen device is not in the external noise mode;
in response to the touchscreen device not being in the external noise mode, determining whether the current standard deviation is greater than a second threshold; and
in response to the current standard deviation being greater than the second threshold, entering the external noise mode.

11. A method comprising:
performing external noise scans at a plurality of sensing frequencies corresponding to ping signal frequencies of wireless chargers;
collecting external noise data from the external noise scans for each of the plurality of sensing frequencies;
calculating a current standard deviation for each of the plurality of sensing frequencies from the collected external noise data;
determining whether the current standard deviation for each of the sensing frequencies exceeds a threshold; and
in response to the current standard deviation exceeding the threshold, entering an external noise mode.

12. The method of claim 11, wherein entering the external noise mode comprises adding a touch delay for reporting touch inputs.

13. The method of claim 11, wherein entering the external noise mode comprises:
determining whether the external noise data on a current frame forms a predetermined shape;
in response to the external noise data not forming the predetermined shape, adding a touch delay for reporting touch inputs; and
in response to the external noise data forming the predetermined shape, adding a heavy touch delay for reporting the touch inputs, wherein the heavy touch delay comprises reporting the touch inputs after more consecutive frames than the touch delay.

14. The method of claim 11, wherein the method further comprises detecting the ping signal frequencies from a plurality of wireless chargers to set as the sensing frequencies for the external noise scans.

15. The method of claim 11, wherein performing the external noise scans at the plurality of sensing frequencies comprises:
performing a first external noise scan for a first frame at a first sensing frequency;
performing a second external noise scan for a second frame at a second sensing frequency; and
performing a third external noise scan for a third frame at a third sensing frequency.

16. The method of claim 15, wherein the first sensing frequency is 175.8 kHz, the second sensing frequency is 140.4 kHz, and the third sensing frequency is 111.1 kHz.

17. The method of claim 15, wherein the first frame, the second frame, and the third frame are non-consecutive frames.

18. The method of claim 15, wherein the method further comprises storing the collected external noise data corresponding to each of the plurality of sensing frequencies in a corresponding FIFO buffer having a size of N×M, wherein N is a sample size and M is a number of sense channels.

19. The method of claim 11, wherein calculating the current standard deviation for each of the plurality of sensing frequencies from the collected external noise data comprises:
calculating an average of the external noise data of N frames for each sense channel for each of the sensing frequencies;
calculating standard deviations for each sense channel for each of the sensing frequencies based on the external noise data for each of the sensing frequencies and the average of the external noise data for the corresponding sense channel; and
determining a maximum standard deviation for each of the sensing frequencies from the standard deviations for each sense channel.

20. A device comprising:
a touchscreen;
a touchscreen controller; and
a non-transitory memory storing a program to be executed by the touchscreen controller, the program comprising instructions to:
perform an external noise scan at a ping signal frequency of an electronic device for a plurality of frames;
collect external noise data from the external noise scan for each frame of the plurality of frames;
store the collected external noise data for each frame in a FIFO buffer;
determine a standard deviation for a current frame from the stored external noise data in the FIFO buffer;
determine whether the standard deviation for the current frame is greater than a threshold; and
operate in an external noise mode in response to the standard deviation for the current frame exceeding the threshold.

21. The device of claim 20, wherein, when operating in the external noise mode, the program comprises instructions to:
determine whether the external noise data on the current frame has a predetermined shape;
in response to the external noise data not having the predetermined shape, add a touch delay for reporting touch inputs; and
in response to the external noise data having the predetermined shape, add a heavy touch delay for reporting touch inputs, wherein the heavy touch delay comprises more frames than the touch delay.

22. The device of claim 20, wherein the program comprises instructions to perform the external noise scan at the ping signal frequency of 111 kHz or in a range of 135-145 kHz or 170-180 kHz.

23. The method of claim 15, wherein the first frame, the second frame, and the third frame are consecutive frames.
